(19) United States
(12) Patent Application Publication
(10) Pub. No.: US 2017/0276562 A1
(43) Pub. Date: Sep. 28, 2017

(54) PRESSURE SENSOR, PRODUCTION METHOD FOR PRESSURE SENSOR, ALTIMETER, ELECTRONIC APPARATUS, AND MOVING OBJECT

(71) Applicant: Seiko Epson Corporation, Tokyo (JP)

(72) Inventor: Hiroyuki SHIMADA, Chuo (JP)

(21) Appl. No.: 15/459,443

(22) Filed: Mar. 15, 2017

(30) Foreign Application Priority Data
Mar. 28, 2016 (JP) 2016-063263

(51) Int. Cl. G01L 9/00; C23C 16/44; C23C 14/34; G01C 5/06

(52) U.S. Cl. CPC G01L 9/0044; G01L 9/0055; G01C 5/06; C23C 16/44; C23C 14/34

(57) ABSTRACT

A pressure sensor includes a flexible diaphragm which is flexed by pressure changes and a coating layer on one surface of the diaphragm. The diaphragm is a single layer containing silicon, nitrogen, and oxygen. Further, the coating layer contains silicon oxynitride. Also, the coating layer has a nitrogen concentration distribution that varies across the thickness of the coating layer.

### BACKGROUND

### 1. Technical Field

The present invention relates to a pressure sensor, a production method for a pressure sensor, an altimeter, an electronic apparatus, and a moving object.

### 2. Related Art

The configuration of a known pressure sensor is described in WO 2009/041463. The pressure sensor described in WO 2009/041463 includes an SOI substrate in which a concave section is formed. A portion overlapping the concave section becomes a diaphragm. A base substrate is bonded to the SOI substrate to close the opening of the concave section. The pressure sensor is configured to measure pressure by detecting the flexural deformation of the diaphragm with a piezoelectric element placed on the diaphragm.

To increase the pressure detection sensitivity of the above pressure sensor, the diaphragm is made easy to flex by reducing the thickness of the diaphragm. This more easily causes a change in stress applied to the piezoelectric element. However, in the pressure sensor described in WO 2009/041463, a silicon oxide film and a silicon nitride film are stacked on the diaphragm. As a result, the diaphragm is thick, and thus hard to flex. Due to this, excellent pressure detection sensitivity cannot be exhibited.

### SUMMARY

An advantage of some aspects of the present disclosure is to provide a pressure sensor having excellent pressure detection sensitivity, a production method for the pressure sensor, and an altimeter, an electronic apparatus, and a moving object, each of which includes the pressure sensor and has high reliability.

The advantage can be achieved by the following configurations.

A pressure sensor according to an aspect of the present disclosure includes a flexible diaphragm which is flexed by pressure changes, and a coating layer on one surface of the diaphragm which is a single layer containing silicon, nitrogen, and oxygen.

Since the coating layer is a single layer, the coating layer can be made thin. As a result, the inhibition of the flexural deformation of the diaphragm by the coating layer can be reduced. Therefore, a pressure sensor having excellent pressure detection sensitivity is obtained. In addition, by containing silicon, oxygen, and nitrogen in the coating layer, the coating layer can exhibit the same function as that of a film in which a silicon oxide film and a silicon nitride film are stacked as in the related art.

In the pressure sensor according to the aspect of the present disclosure, it is preferred that the coating layer contains silicon oxynitride.

According to this configuration, the surface of the diaphragm can be effectively protected.

In the pressure sensor according to the aspect of the present disclosure, it is preferred that the coating layer has a nitrogen concentration distribution that varies in the thickness direction of the coating layer.

According to this configuration, the coating layer can be made to have different functions.

In the pressure sensor according to the aspect of the present disclosure, it is preferred that the nitrogen concentration distribution gradually increases from a first side of the coating layer adjacent the diaphragm to a second side of the coating layer opposite to the first side.

According to this configuration, the coating layer can have different functions with a relatively simple configuration.

In the pressure sensor according to the aspect of the present disclosure, it is preferred that when the thickness of the diaphragm is denoted by T1 and the thickness of the coating layer is denoted by T2, the following relationship is satisfied: T2≦T1/20.

According to this configuration, the coating layer can be made sufficiently thin.

A production method for a pressure sensor according to an aspect of the present disclosure includes preparing a substrate, providing a coating layer on one surface of the substrate which is a single layer containing silicon, nitrogen, and oxygen, and forming a flexible diaphragm in the substrate, the diaphragm being flexed due to pressure changes.

According to this configuration, the diaphragm can be made thin, and a pressure sensor having excellent pressure detection sensitivity can be produced.

In the production method for a pressure sensor according to the aspect of the present disclosure, it is preferred that the substrate contains silicon, and in the providing of the coating layer, the one surface of the substrate is heated in an atmosphere containing nitrogen and oxygen to form the coating layer.

According to this configuration, the coating layer can be relatively easily formed.

In the production method for a pressure sensor according to the aspect of the present disclosure, it is preferred that the substrate contains silicon, and in the providing of the coating layer, the one surface of the substrate is heated in an atmosphere containing oxygen, and thereafter is heated in a nitrogen atmosphere to form the coating layer.

According to this configuration, a coating layer having a nitrogen concentration distribution that varies across the thickness of the coating layer can be relatively easily formed.

An altimeter according to an aspect of the present disclosure includes the pressure sensor according to the aspect of the invention.

According to this configuration, an altimeter having high reliability can be obtained.

An electronic apparatus according to an aspect of the present disclosure includes the pressure sensor according to the aspect of the invention.

According to this configuration, an electronic apparatus having high reliability can be obtained.

A moving object according to an aspect of the present disclosure includes the pressure sensor according to the aspect of the invention.

According to this configuration, a moving object having high reliability can be obtained.

### BRIEF DESCRIPTION OF THE DRAWINGS

Embodiments of the present invention will be described with reference to the accompanying drawings, wherein like numbers reference like elements.

FIG. 1 is a cross-sectional view of a pressure sensor according to a first embodiment of the invention.

FIG. 2 is an enlarged cross-sectional view of a diaphragm included in the pressure sensor shown in FIG. 1.

FIG. 3 is a cross-sectional view showing a modification of the pressure sensor shown in FIG. 1.

FIG. 4 is a plan view showing a sensor section included in the pressure sensor shown in FIG. 1.

FIG. 5 is a view showing a bridge circuit including the sensor section shown in FIG. 4.

FIG. 6 is a flowchart showing a production method for the pressure sensor shown in FIG. 1.

FIG. 7 is a cross-sectional view for illustrating the production method for the pressure sensor shown in FIG. 1.

FIG. 8 is a cross-sectional view for illustrating the production method for the pressure sensor shown in FIG. 1.

FIG. 9 is a cross-sectional view for illustrating the production method for the pressure sensor shown in FIG. 1.

FIG. 10 is a cross-sectional view for illustrating the production method for the pressure sensor shown in FIG. 1.

FIG. 11 is a cross-sectional view for illustrating the production method for the pressure sensor shown in FIG. 1.

FIG. 12 is a view showing the nitrogen and oxygen concentration distributions in a coating layer included in a pressure sensor according to a second embodiment of the invention.

FIG. 13 is a cross-sectional view showing a production method for the coating layer shown in FIG. 12.

FIG. 14 is a cross-sectional view showing the production method for the coating layer shown in FIG. 12.

FIG. 15 is a cross-sectional view of a pressure sensor according to a third embodiment of the invention.

FIG. 16 is a perspective view showing one example of an altimeter according to the invention.

FIG. 17 is a front view showing one example of an electronic apparatus according to the invention.

FIG. 18 is a perspective view showing one example of a moving object according to the invention.

### DESCRIPTION OF EXEMPLARY EMBODIMENTS

Hereinafter, a pressure sensor, a production method for a pressure sensor, an altimeter, an electronic apparatus, and a moving object will be described in detail based on embodiments shown in the accompanying drawings.

### First Embodiment

First, a pressure sensor according to a first embodiment will be described.

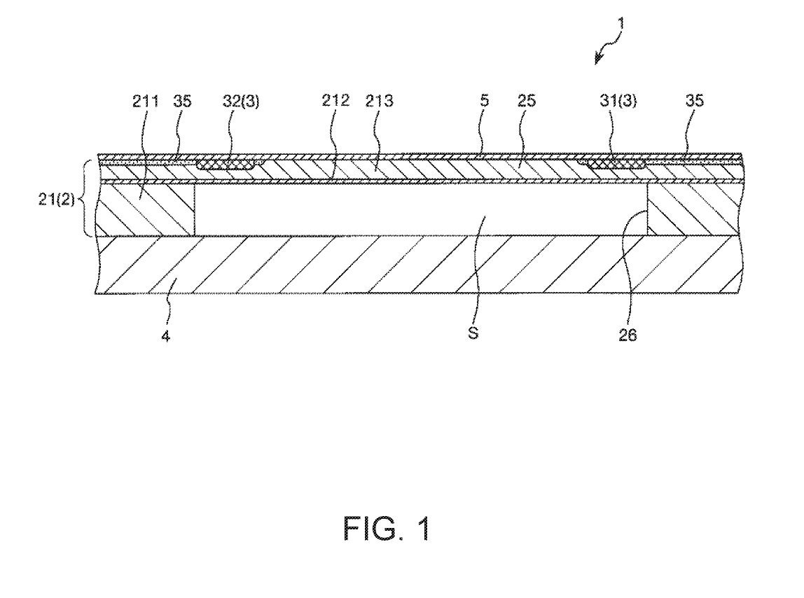

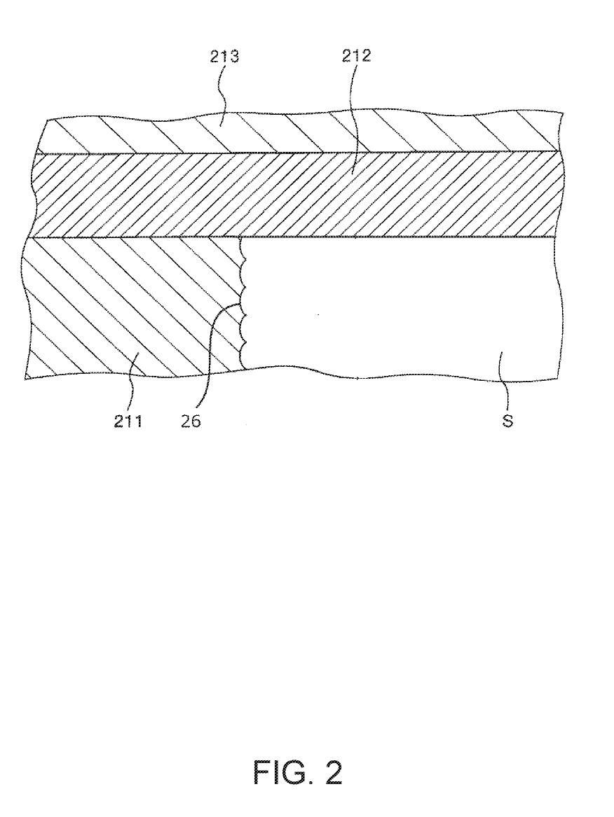

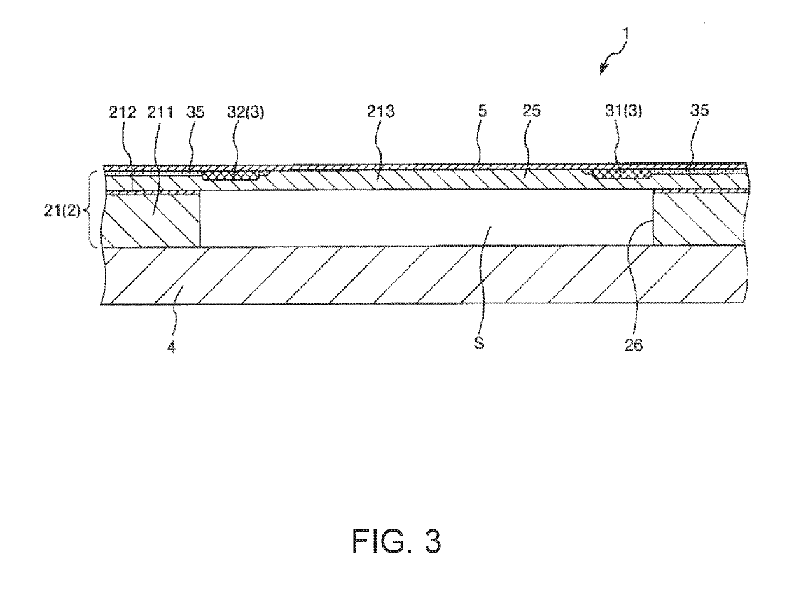

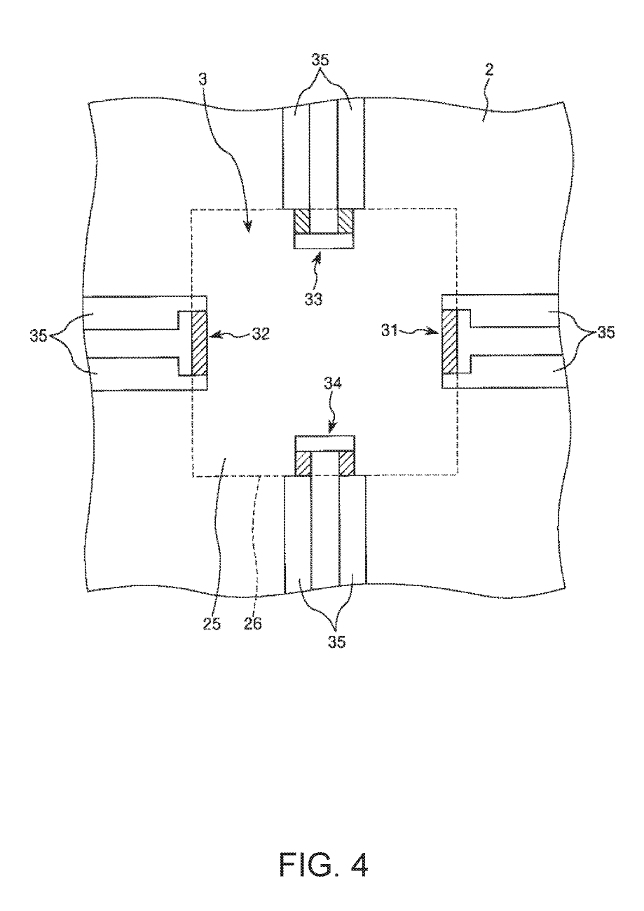

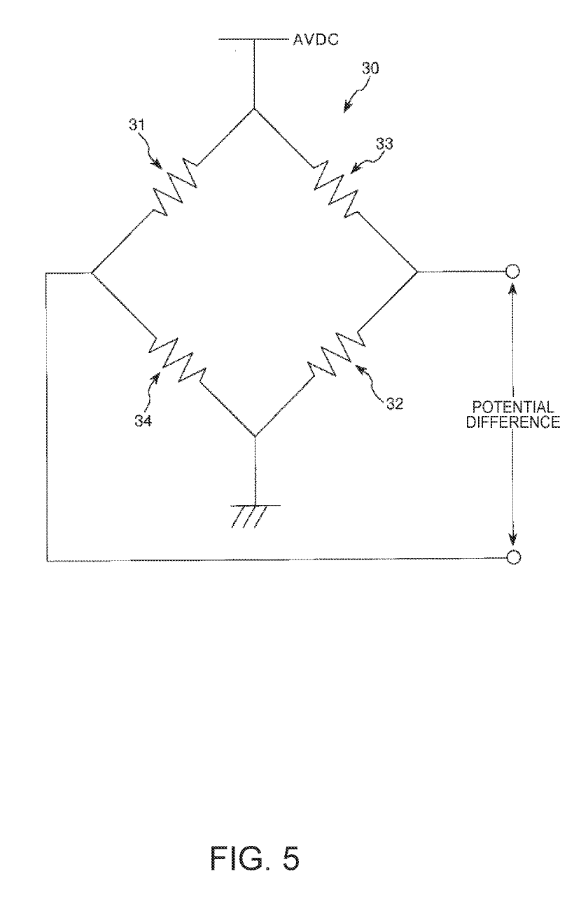

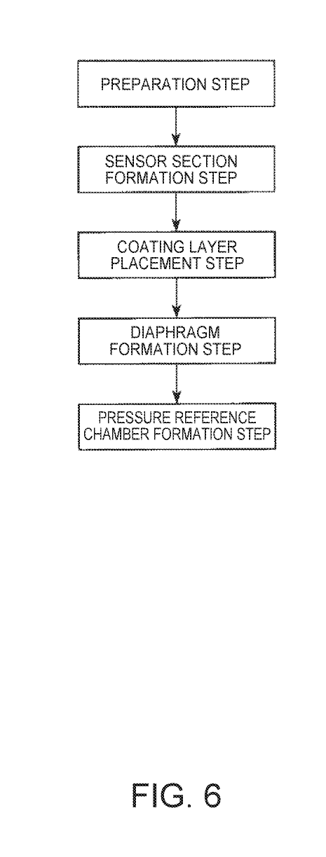

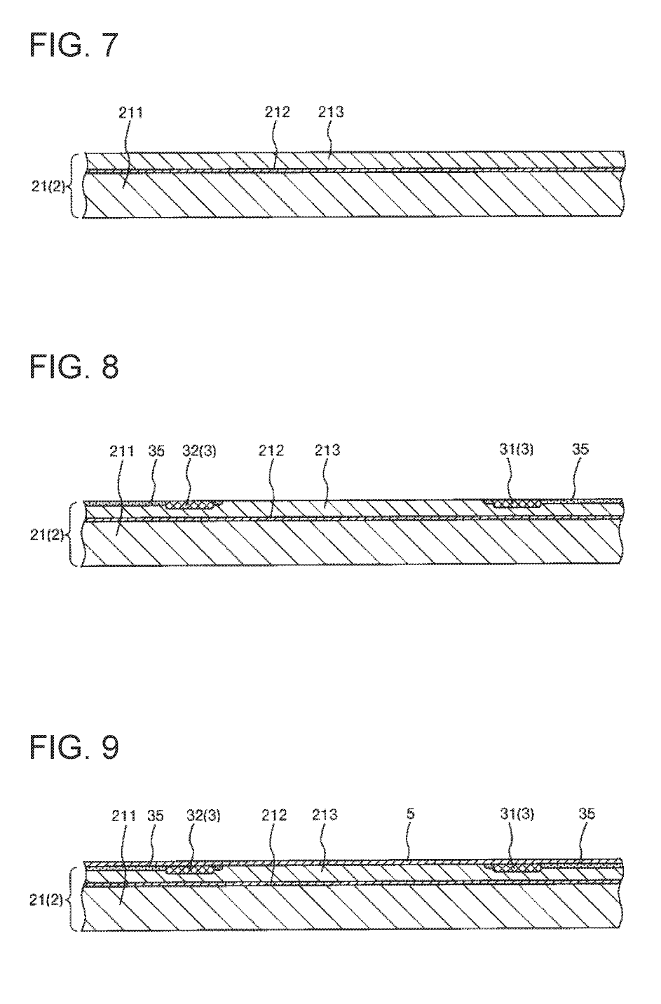

FIG. 1 is a cross-sectional view of the pressure sensor according to the first embodiment. FIG. 2 is an enlarged cross-sectional view of a diaphragm included in the pressure sensor shown in FIG. 1. FIG. 3 is a cross-sectional view showing a modification of the pressure sensor shown in FIG. 1. FIG. 4 is a plan view showing a sensor section included in the pressure sensor shown in FIG. 1. FIG. 5 is a view showing a bridge circuit including the sensor section shown in FIG. 4. FIG. 6 is a flowchart showing a production method for the pressure sensor shown in FIG. 1. FIGS. 7 to 11 are each a cross-sectional view for illustrating the production method for the pressure sensor shown in FIG. 1. In the following description, the upper side and the lower side in FIG. 1 are also referred to as “upper” and “lower”, respectively. Further, a plan view of a substrate 2 (a plan view viewed from the upper side in FIG. 1) is also simply referred to as “a plan view”.

As shown in FIG. 1, a pressure sensor 1 includes a diaphragm 25 which is flexurally deformed (flexes) by receiving a pressure (pressure changes) and a coating layer 5 which is composed of a single layer and is on one surface of the diaphragm 25, and the coating layer 5 contains silicon (Si), nitrogen (N), and oxygen (O). By composing the coating layer 5 of a single layer in this manner, the coating layer 5 can be made thin. Due to this, the inhibition of the flexural deformation of the diaphragm 25 by the coating layer 5 can be reduced. Therefore, a pressure sensor 1 having excellent pressure detection sensitivity (in other words, a pressure sensor 1 in which the decrease in the pressure detection sensitivity is suppressed) is obtained. In addition, by containing silicon (Si), oxygen (O), and nitrogen (N) in the coating layer 5, the coating layer 5 can exhibit the same function as that of a stacked film in which a silicon oxide film and a silicon nitride film are stacked as a pressure sensor in the related art. Hereinafter, the pressure sensor 1 will be described in detail.

As shown in FIG. 1, such a pressure sensor 1 includes a substrate 2, a sensor section 3 on the substrate 2, the coating layer 5 on the upper surface of the substrate 2, a base substrate 4 bonded to the lower surface of the substrate 2, and a pressure reference chamber S (hollow area) formed between the substrate 2 and the base substrate 4.

### Substrate

As shown in FIG. 1, the substrate 2 is constituted by an SOI substrate 21 (that is, a substrate in which a first silicon layer 211, a silicon oxide layer 212, and a second silicon layer 213 are sequentially stacked in this order). The substrate 2 is not limited to the SOI substrate, and for example, a silicon substrate may be used.

Further, as shown in FIG. 1, the diaphragm 25 is provided in the substrate 2. The diaphragm 25 is thinner than the peripheral portion of the substrate 2 and is flexurally deformed by receiving pressure changes. In the SOI substrate 21, a concave section 26 which is open to a lower portion thereof is formed, and the diaphragm 25 is formed along a bottom portion of the concave section 26. In this embodiment, the plan view shape of the diaphragm 25 is a substantial square, however, the plan view shape of the diaphragm 25 is not particularly limited, and may be, for example, a circle.

In this embodiment, the concave section 26 is formed by dry etching using a silicon deep etching apparatus. Specifically, the concave section 26 is formed by carving the first silicon layer 211 from the lower surface side of the SOI substrate 21 by repeating a step of isotropic etching, formation of a protective film, and anisotropic etching. This step is repeated, and when etching reaches the silicon oxide layer 212, the silicon oxide layer 212 serves as an etching stopper, and therefore, etching is stopped, whereby the concave section 26 is obtained. By repeating the above-mentioned step, as shown in FIG. 2, periodic irregularities are formed in the carving direction on the side surface of the inner wall of the concave section 26.

The formation method for the diaphragm 25 is not limited to the above-mentioned method, and the diaphragm 25 may be formed by, for example, wet etching. Further, as shown in FIG. 3, the silicon oxide layer 212 may be removed from the lower surface of the diaphragm 25. That is, the diaphragm 25 maybe constituted by a single layer of the second silicon layer 213. In this way, the diaphragm 25 can be made thinner.

The thickness of the diaphragm 25 is the thickness in the direction orthogonal to the planar direction of the diaphragm and is the average thickness.

For example, in the case of a diaphragm in the shape of a square with a side length of 125 μm, the thickness (average thickness) of the diaphragm 25 is not particularly limited, but is preferably 1 μm or more and 10 μm or less, more preferably 1 μm or more and 5 μm or less, further more preferably 1 μm or more and 3 μm or less. By being in such a range, the diaphragm 25 is sufficiently thin, and is easily flexurally deformed by pressure changes, and is likely to cause a change in stress applied to the sensor section 3 (the below-mentioned piezoresistive elements 31, 32, 33, and 34) while ensuring the mechanical strength of the diaphragm 25 is maintained. Due to this, the pressure detection sensitivity of the pressure sensor 1 can be increased.

### Sensor Section

As shown in FIG. 4, the sensor section 3 includes four piezoresistive elements 31, 32, 33, and 34 (portions indicated by hatching in FIG. 4 are the piezoresistive elements) provided in the diaphragm 25. The four piezoresistive elements 31, 32, 33, and 34 are electrically connected to one another through a wiring 35 or the like and form a bridge circuit 30 (Wheatstone bridge circuit) shown in FIG. 5. A drive circuit (not shown) which supplies a drive voltage AVDC is connected to the bridge circuit 30. The bridge circuit 30 outputs a detection signal (voltage) in accordance with the change in the resistance value of the piezoresistive element 31, 32, 33, or 34 based on the flexing of the diaphragm 25. Due to this, a pressure received by the diaphragm 25 can be detected based on this output detection signal. In this manner, a pressure can be accurately detected based on the output from the bridge circuit 30. The bridge circuit 30 may be formed in the pressure sensor 1 or may be connected to an external device such as an IC.

In particular, the piezoresistive elements 31, 32, 33, and 34 are placed along the periphery of the diaphragm 25. When the diaphragm 25 is flexurally deformed by pressure, a large stress is applied to a peripheral portion of the diaphragm 25, and therefore, by placing the piezoresistive elements 31, 32, 33, and 34 at the peripheral portions, the detection signal is increased, and therefore, the pressure detection sensitivity is improved. The placement of the piezoresistive elements 31, 32, 33, and 34 is not particularly limited, and for example, the piezoresistive elements 31, 32, 33, and 34 may be placed across the periphery of the diaphragm 25.

Each of the piezoresistive elements 31, 32, 33, and 34 can be constituted by, for example, doping (diffusing or injecting) an impurity such as phosphorus or boron into the second silicon layer 213 of the SOI substrate 21. Further, the wiring 35 can be constituted by, for example, doping (diffusing or injecting) an impurity such as phosphorus or boron into the second silicon layer 213 of the SOI substrate at a higher concentration than in the piezoresistive elements 31, 32, 33, and 34.

### Coating Layer

As shown in FIG. 1, the coating layer 5 is provided on the upper surface of the substrate 2 and covers the sensor section 3. The coating layer 5 contains silicon (Si), nitrogen (N), and oxygen (O) as described above. More specifically, the coating layer 5 contains silicon oxynitride (SiON), and is particularly composed of silicon oxynitride in this embodiment. By containing silicon oxynitride in the coating layer 5, the sensor section 3 on the surface of the diaphragm 25 can be effectively protected. More specifically, with the coating layer 5 provided in this way, the interface states of the piezoresistive elements 31, 32, 33, and 34 can be reduced, and therefore, the occurrence of noise can be suppressed, and also the sensor section 3 can be protected from the penetration of water or dust. In this manner, according to this embodiment, the effect exhibited by a stacked body of a silicon oxide film and a silicon nitride film in the related art can be exhibited by a single layer, and therefore, while exhibiting the same effect, the coating layer 5 can be made thinner.

The thickness of the coating layer is the thickness of the portion arranged on the upper surface of the diaphragm 25. This thickness is the thickness in the direction orthogonal to the planar direction of the diaphragm and is the average thickness.

The thickness of the coating layer 5 is preferably as thin as possible yet still enabling the coating layer 5 to function. Thus, the thickness of the coating layer 5 is not particularly limited, however, when the thickness of the diaphragm 25 is denoted by T1 and the thickness of the coating layer 5 is denoted by T2, it is preferred to satisfy the following relationship: T2≦T1/20, it is more preferred to satisfy the following relationship: T2≦T1/50, and it is further more preferred to satisfy the following relationship: T2≦T1/100. By being within such a range, a coating layer 5 which is sufficiently thin is formed, and therefore, the coating layer 5 is less likely to inhibit the flexural deformation of the diaphragm 25. The lower limit of the thickness of the coating layer 5 is not particularly limited and varies depending on the formation method for the coating layer 5, but is preferably, for example, 0.005 μm.

### Base Substrate

As shown in FIG. 1, the base substrate 4 is bonded to the lower surface of the substrate 2 (the surface of the first silicon layer 211) so as to close the opening of the concave section 26. By hermetically sealing the concave section 26 with the base substrate 4, the pressure reference chamber S is formed. The pressure reference chamber S is preferably in a vacuum state (for example, 10 Pa or less). In this way, the pressure sensor 1 can be used as a so-called “absolute pressure sensor” which detects a pressure with reference to vacuum, and therefore, the pressure sensor 1 has high convenience. However, the pressure in the pressure reference chamber S is not particularly limited.

As such a base substrate 4, for example, a silicon substrate, a glass substrate, a ceramic substrate, or the like can be used. Further, the base substrate 4 is sufficiently thick with respect to the diaphragm 25 so that a portion facing the diaphragm 25 is not deformed by a differential pressure (a difference between the pressure in the pressure reference chamber S and the environmental pressure) through the pressure reference chamber S.

Next, a production method for the pressure sensor 1 will be described. As shown in FIG. 6, the production method for the pressure sensor 1 includes a preparation step of preparing the substrate 2, a sensor section formation step of forming the sensor section 3 in the substrate 2, a coating layer formation step of providing the coating layer 5 composed of a single layer containing silicon, nitrogen, and oxygen on one surface of the substrate 2, a diaphragm formation step of forming the diaphragm 25 which is flexurally deformed by receiving a pressure in the substrate 2, and a pressure reference chamber formation step of forming the pressure reference chamber S by bonding the base substrate 4 to the substrate 2.

### Preparation Step

First, as shown in FIG. 7, as the substrate 2, the SOI substrate 21 in which the first silicon layer 211, the silicon oxide layer 212, and the second silicon layer 213 are stacked is prepared.

### Sensor Section Formation Step

Subsequently, as shown in FIG. 8, the sensor section 3 (piezoresistive elements 31, 32, 33, and 34 and the wiring 35) is formed by injecting an impurity such as phosphorus or boron into the upper surface of the substrate 2 (the surface of the second silicon layer 213).

### Coating Layer Formation Step

Subsequently, the upper surface (one surface) of the substrate 2 is heated in an atmosphere containing nitrogen and oxygen. The heating temperature is not particularly limited, but is preferably 800° C. or higher and 1000° C. or lower. Since the upper surface of the substrate 2 (the second silicon layer 213) contains silicon, the upper surface of the substrate 2 is directly thermally oxynitrided (oxidized and nitrided), and as shown in FIG. 9, the coating layer 5 composed of silicon oxynitride is formed on the upper surface of the substrate 2. As the nitrogen in the atmosphere, for example, at least one of NO, N₂O, NO₂, and NH₃ can be used, and as the oxygen, for example, O₂ or O₂ and H₂O can be used. According to such a method, the coating layer 5 composed of silicon oxynitride can be relatively easily formed. Further, according to such a method, the coating layer 5 which is homogeneous can be formed. In addition, it is easier to form the coating layer 5 thinly as compared with sputtering or CVD. In the above-mentioned method, the heating temperature is about 800° C. or higher and 1000° C. or lower, however, by utilizing an oxygen plasma, it is also possible to decrease the heating temperature to about 400° C. According to this, the thermal history can be reduced.

### Diaphragm Formation Step

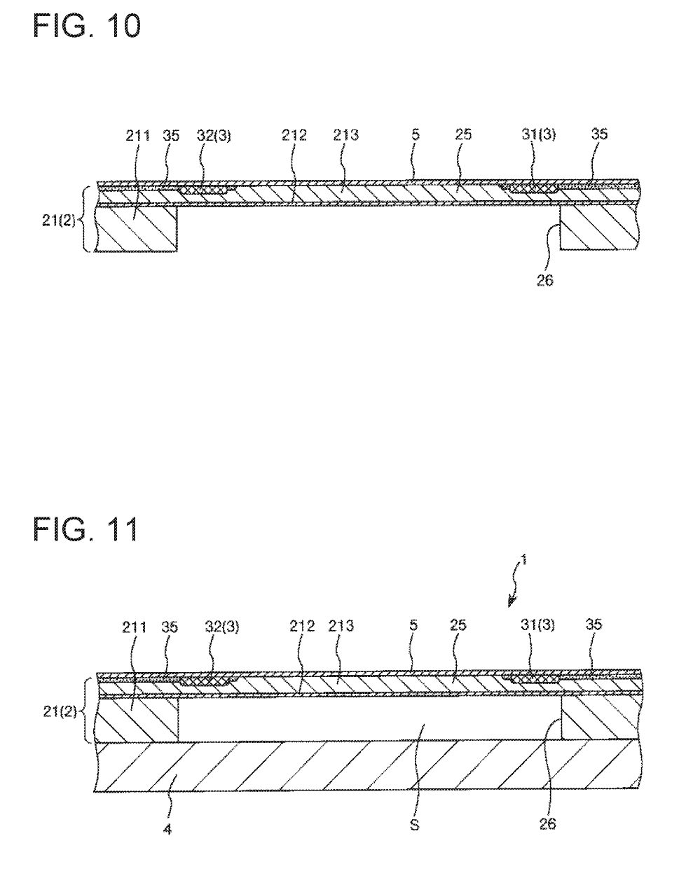

Subsequently, as shown in FIG. 10, the concave section 26 which is open to the lower portion of the substrate is formed by dry etching using a silicon deep etching apparatus. By doing this, the diaphragm 25 is formed along a bottom portion of the concave section 26. The formation method for the concave section 26 is not particularly limited, and the concave section 26 may be formed by wet etching.

### Pressure Reference Chamber Formation Step

Subsequently, the base substrate 4 is prepared, and as shown in FIG. 11, the base substrate 4 is bonded to the lower surface of the substrate 2 in a vacuum environment. By doing this, the pressure reference chamber S in a vacuum state is formed between the base substrate 4 and the substrate 2.

As described above, the pressure sensor 1 is obtained. According to such a production method, the diaphragm 25 can be made thin, and therefore, the pressure sensor 1 having excellent pressure detection sensitivity can be produced. In the above-mentioned production method, the diaphragm formation step is performed after the coating layer formation step, however, the order of the diaphragm formation step is not limited thereto, and the diaphragm formation step may be performed prior to the coating layer formation step (for example, between the preparation step and the sensor section formation step, or between the sensor section formation step and the coating layer formation step).

### Second Embodiment

Next, a pressure sensor according to a second embodiment of the invention will be described.

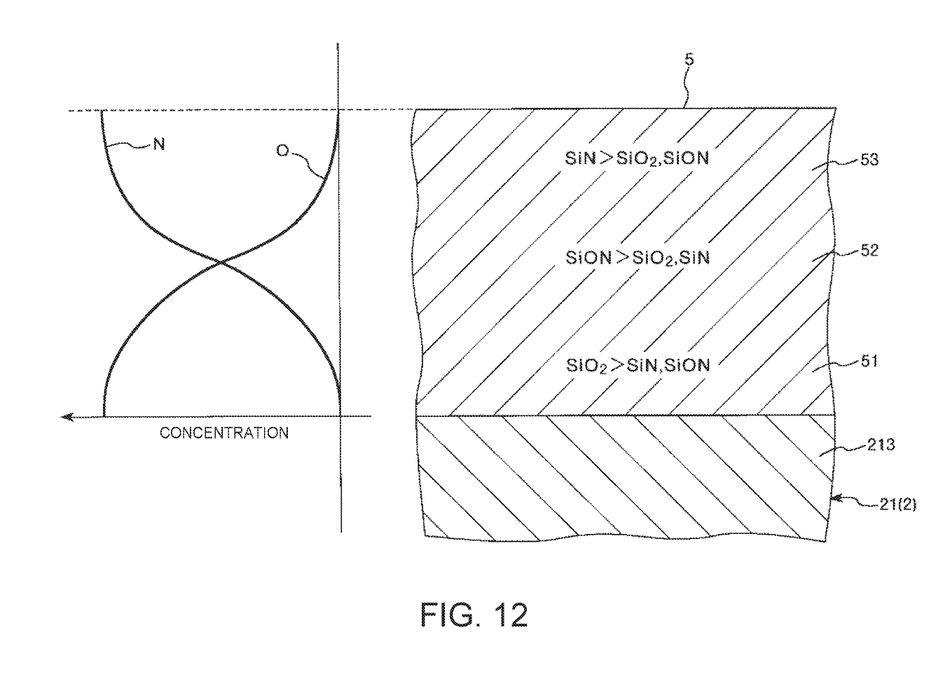

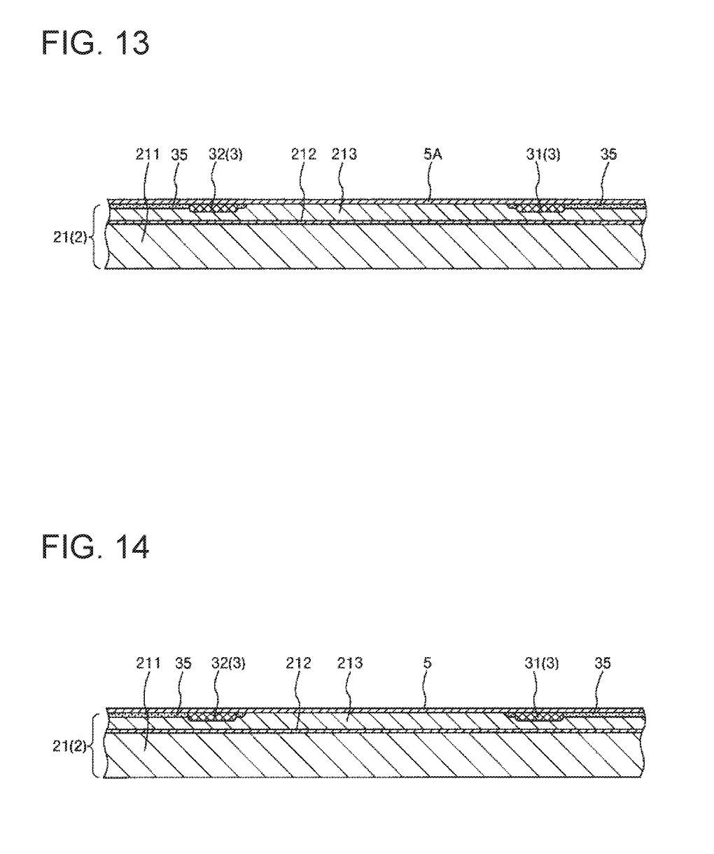

FIG. 12 is a view showing the nitrogen and oxygen concentration distributions in a coating layer included in the pressure sensor according to the second embodiment of the invention. FIGS. 13 and 14 are each a cross-sectional view showing the production method for the coating layer shown in FIG. 12.

Hereinafter, with respect to the pressure sensor according to the second embodiment, different points from the above-mentioned embodiment will be mainly described, and the description of the same matter will be omitted.

The pressure sensor according to the second embodiment is the same as the pressure sensor according to the first embodiment described above except that the configuration of the coating layer is different. The same components as those of the above-mentioned embodiment are denoted by the same reference numerals.

The coating layer 5 of this embodiment has a nitrogen (N) concentration distribution that varies in the thickness direction of the coating layer 5, and also has an oxygen (O) concentration distribution that varies in the thickness direction of the coating layer 5. That is, the coating layer 5 has a portion in which the concentration (content) of nitrogen varies in the thickness direction, and also has a portion in which the concentration (content) of oxygen varies in the thickness direction. Since the coating layer 5 has varying nitrogen and oxygen concentration distributions therein, the function of the coating layer 5 can be made different in the thickness direction.

Specifically, as shown in FIG. 12, the coating layer 5 has a concentration (atm %) of nitrogen that gradually increases from the lower surface side (the diaphragm 25 side) to the upper surface side (the opposite side to the diaphragm 25) and also has a concentration (atm %) of oxygen that gradually decreases from the lower surface side to the upper surface side. Thus, the coating layer 5 has a central region 52 (a region having a high silicon oxynitride content) which is located in a central portion in the thickness direction and contains more silicon oxynitride than silicon oxide or silicon nitride, a lower region 51 (a region having a high silicon oxide content) which is located on the lower side of the central region 52 and contains more silicon oxide than silicon oxynitride or silicon nitride, and an upper region 53 (a region having a high silicon nitride content) which is located on the upper side of the central region 52 and contains more silicon nitride than silicon oxynitride or silicon oxide. According to such a configuration, the coating layer 5 can have different functions with a relatively simple configuration. Specifically, in the lower region 51, a function to suppress the occurrence of noise by reducing the interface states of the piezoresistive elements 31, 32, 33, and 34 is mainly exhibited, and in the upper region 53, a function to protect the sensor section 3 from the penetration of water or dust is mainly exhibited, and in the central region 52, these two functions are both exhibited.

In particular, in this embodiment, a portion on the lower side in the lower region 51 (that is, the lower surface of the coating layer 5 and the vicinity thereof) is composed of silicon oxide, and a portion on the upper side in the upper region 53 (that is, the upper surface of the coating layer 5 and the vicinity thereof) is composed of silicon nitride. According to such a configuration, the respective functions of the lower region 51 and the upper region 53 are further improved. That is, a single layer structure includes one example of a layer in which the concentration of oxygen or nitrogen changes continuously as in this embodiment. On the other hand, a case where layers in which the concentration of oxygen or the concentration of nitrogen changes discontinuously are stacked is one example of a stacked structure.

Next, a production method for this pressure sensor 1 will be described. The production method for the pressure sensor 1 includes a preparation step, a sensor section formation step, a coating layer formation step, a diaphragm formation step, and a pressure reference chamber formation step in the same manner as in the above-mentioned embodiment. The steps other than the coating layer formation step are the same as in the above-mentioned embodiment, and therefore, the description thereof will be omitted.

### Coating Layer Formation Step

In this step, the upper surface (one surface) of the substrate 2 is heated in an atmosphere containing oxygen, and thereafter is heated (directly thermally oxidized) in a nitrogen atmosphere. Specifically, first, the upper surface (one surface) of the substrate 2 is heated in an atmosphere containing, for example, O₂ (which may further contains H₂O) as the raw material of oxygen at about 800° C. or higher and 1000° C. or lower. Since the upper surface of the substrate 2 (the second silicon layer 213) contains silicon, by this first heating, a silicon oxide layer 5A is formed on the upper surface of the substrate 2 as shown in FIG. 13. Subsequently, the upper surface of the substrate 2 (that is, the surface of the silicon oxide layer 5A) is heated (directly thermally nitrided) in an atmosphere containing, for example, at least one of NO, N₂O, NO₂, and NH₃ as the raw material of nitrogen at 800° C. or higher and 1000° C. or lower. By doing this, a portion on the upper surface side of the silicon oxide layer 5A is nitrided, and as shown in FIG. 14, the coating layer 5 containing silicon, oxygen, and nitrogen is formed. Such a coating layer 5 is easily nitrided on the upper surface side and is hardly nitrided on the lower surface side, and therefore, the lower region 51 having a high silicon oxide content, the central region 52 having a high silicon oxynitride content, and the upper region 53 having a high silicon nitride content as described above are formed. According to such a method, the coating layer 5 having a varied nitrogen concentration distribution in the thickness direction can be relatively easily formed.

In the above-mentioned oxidizing step and nitriding step, the heating temperature is set to about 800° C. or higher and 1000° C. or lower, however, by utilizing an oxygen plasma or a nitrogen plasma, it is possible to decrease the heating temperature to about 400° C. According to this, the thermal history can be reduced.

Also according to such a second embodiment, the same effect as that of the above-mentioned first embodiment can be exhibited.

### Third Embodiment

Next, a pressure sensor according to a third embodiment of the invention will be described.

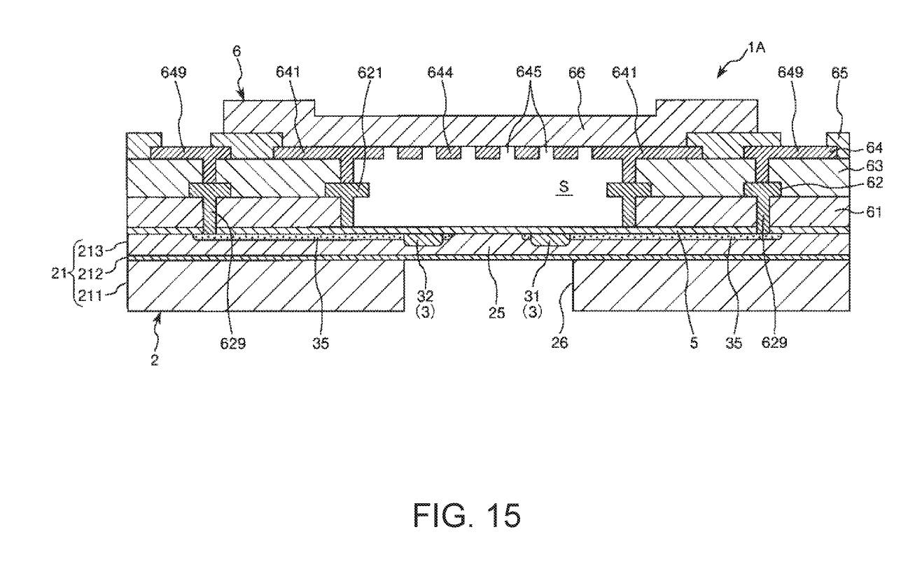

FIG. 15 is a cross-sectional view of a pressure sensor according to a third embodiment of the invention.

Hereinafter, with respect to the pressure sensor according to the third embodiment, different points from the above-mentioned embodiments will be mainly described, and the description of the same matter will be omitted.

A pressure sensor 1A shown in FIG. 15 includes a substrate 2, a sensor section 3, a coating layer 5, a surrounding structure 6, and a pressure reference chamber S (hollow area). The configurations of the substrate 2, the sensor section 3, the coating layer 5, and the pressure reference chamber S are the same as those of the above-mentioned first embodiment, respectively, and therefore, the surrounding structure 6 will be mainly described.

### Surrounding Structure

The surrounding structure 6 forms the pressure reference chamber S between the structure 6 and the substrate 2. Such a surrounding structure 6 includes an interlayer insulating film 61 on the substrate 2, a wiring layer 62 on the interlayer insulating film 61, an interlayer insulating film 63 on the wiring layer 62 and the interlayer insulating film 61, a wiring layer 64 on the interlayer insulating film 63, a surface protective film 65 on the wiring layer 64 and the interlayer insulating film 63, and a sealing layer 66 on the wiring layer 64 and the surface protective film 65.

The wiring layer 62 includes a frame-shaped wiring section 621 surrounding the pressure reference chamber S and a wiring section 629 electrically connected to the sensor section 3. Similarly, the wiring layer 64 includes a frame-shaped wiring section 641 surrounding the pressure reference chamber S and a wiring section 649 electrically connected to the sensor section 3. The sensor section 3 is drawn out on the upper surface of the surrounding structure 6 by the wiring sections 629 and 649.

Further, the wiring layer 64 includes a coating layer 644 located on the ceiling of the pressure reference chamber S. A plurality of through-holes 645 communicating inside and outside the pressure reference chamber S are provided in the coating layer 644. Such a coating layer 644 is integrally formed with the wiring section 641, and is placed so as to face the diaphragm 25 with the pressure reference chamber S interposed therebetween. The plurality of through-holes 645 are holes for release etching when a sacrificial layer filled in the unfinished pressure reference chamber S is removed. Further, the sealing layer 66 is placed on the coating layer 644, and the through-holes 645 are sealed by the sealing layer 66.

The surface protective film 65 has a function to protect the surrounding structure 6 from water, dust, scratches, and the like. Such a surface protective film 65 is placed on the interlayer insulating film 63 and the wiring layer 64 so as to not close the through-holes 645 of the coating layer 644.

In such a surrounding structure 6, an insulating film such as, for example, a silicon oxide film (SiO₂ film) can be used as the interlayer insulating films 61 and 63. Further, a metal film such as, for example, an aluminum film can be used as the wiring layers 62 and 64. In addition, a metal film of, for example, Al, Cu, W, Ti, TiN, or the like, a silicon oxide film, or the like can be used as the sealing layer 66. A silicon oxide film, a silicon nitride film, a polyimide film, an epoxy resin film, or the like, for example, can be used as the surface protective film 65.

Also according to such a third embodiment, the same effect as that of the above-mentioned first embodiment can be exhibited.

### Fourth Embodiment

Next, an altimeter according to a fourth embodiment of the invention will be described.

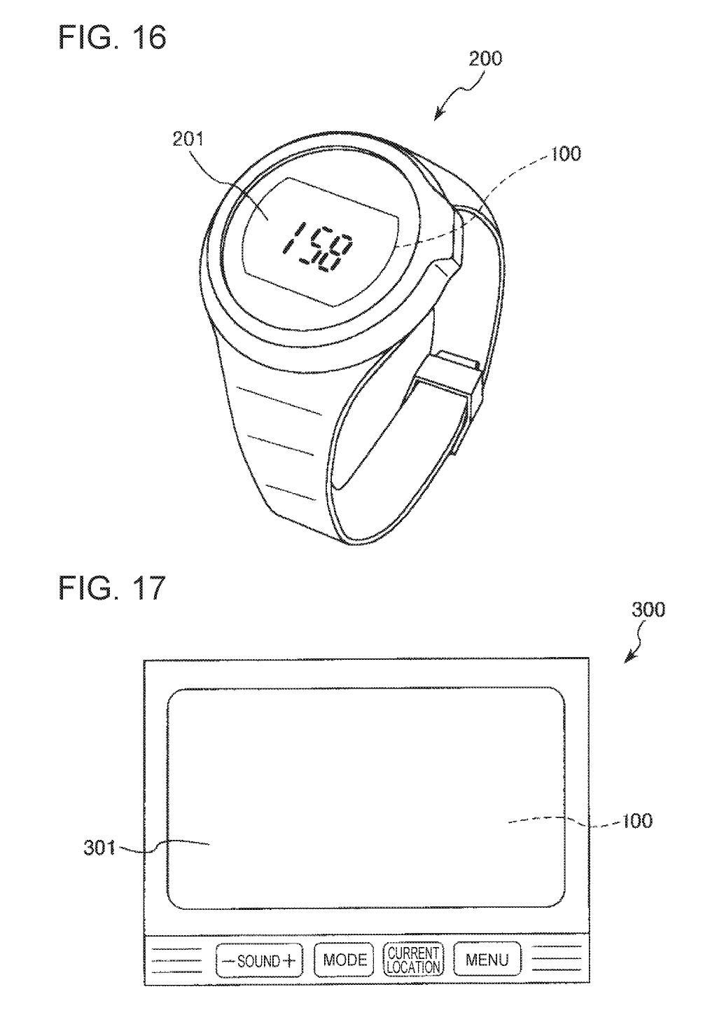

FIG. 16 is a perspective view showing one example of an altimeter according to the invention.

An altimeter 200 shown in FIG. 16 can be worn on the wrist like a wristwatch. In the altimeter 200, the pressure sensor 1 is mounted, and the altitude of the current location above sea level, the atmospheric pressure of the current location, or the like can be displayed on a display section 201. In this display section 201, various pieces of information such as a current time, the heart rate of a user, or weather can be displayed other than these. Such an altimeter 200 includes the pressure sensor 1 having excellent detection accuracy, and therefore can exhibit high reliability. The altimeter 200 may include the pressure sensor 1A in place of the pressure sensor 1.

If the altimeter 200 has a waterproof function, the altimeter 200 can also be used as, for example, a water depth gauge for diving or free diving.

### Fifth Embodiment

Next, an electronic apparatus according to a fifth embodiment of the invention will be described.

FIG. 17 is a front view showing one example of an electronic apparatus according to the invention.

The electronic apparatus shown in FIG. 17 is a navigation system 300 including the pressure sensor 1. The navigation system 300 includes map information (not shown), a location information acquisition unit based on a GPS (Global Positioning System), a self-contained navigation unit based on a gyroscope, an accelerometer, and a vehicle speed data, the pressure sensor 1, and a display section 301 which displays given location information or route information.

According to this navigation system 300, in addition to the acquired location information, altitude information can be acquired by the pressure sensor 1. Due to this, by detecting the change in altitude by entering an elevated road from a general road (or vice versa), it is possible to determine whether a vehicle travels on a general road or an elevated road, and the navigation information of the actual traveling state can be provided to a user. Such a navigation system 300 includes the pressure sensor 1 having excellent detection accuracy and therefore can exhibit high reliability. The navigation system 300 may include the pressure sensor 1A in place of the pressure sensor 1.

The electronic apparatus including the pressure sensor according to the invention is not limited to the above-mentioned navigation system, and can be applied to, for example, a personal computer, a cellular phone, a smartphone, a tablet terminal, a wearable terminal such as an HMD (head-mounted display), a timepiece (including a smart watch), a medical apparatus (for example, an electronic thermometer, a sphygmomanometer, a blood glucose meter, an electrocardiographic apparatus, an ultrasonic diagnostic apparatus, or an electronic endoscope), various measurement apparatuses, meters and gauges (for example, meters and gauges for vehicles, aircrafts, and ships), a flight simulator, and the like.

### Sixth Embodiment

Next, a moving object according to a sixth embodiment of the invention will be described.

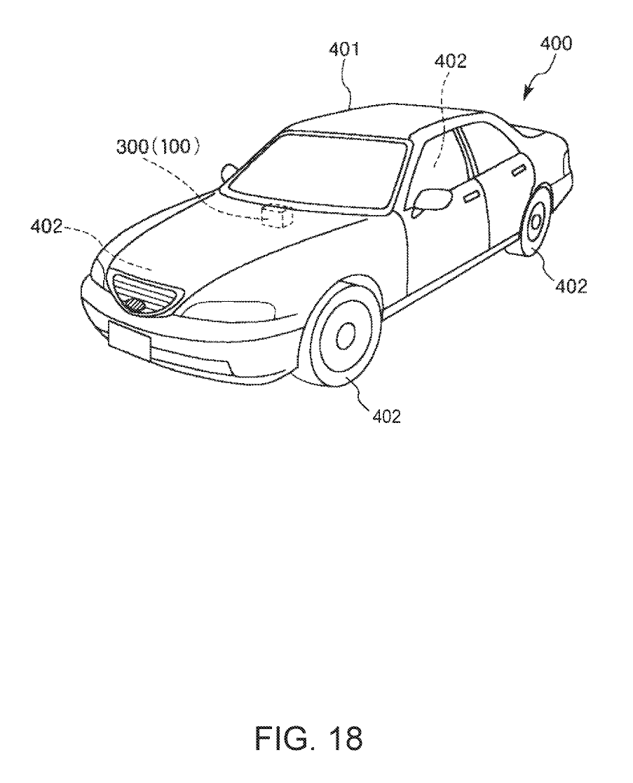

FIG. 18 is a perspective view showing one example of a moving object according to the invention.

The moving object shown in FIG. 18 is a car 400 including the pressure sensor 1. The car 400 includes a car body 401 and four wheels 402, and is configured to rotate the wheels 402 by a power source (engine) (not shown) provided in the car body 401. Such a car 400 includes the pressure sensor 1 having excellent detection accuracy and therefore can exhibit high reliability. The car 400 may include the pressure sensor 1A in place of the pressure sensor 1.

Hereinabove, the pressure sensor, the production method for a pressure sensor, the altimeter, the electronic apparatus, and the moving object according to the invention have been described based on the respective embodiments shown in the drawings, however, the invention is not limited thereto, and the configuration of each section can be replaced with an arbitrary configuration having the same function. Further, another arbitrary component or step may be added, and also the respective embodiments maybe appropriately combined with each other.

Further, in the above-mentioned embodiments, as the sensor section, a sensor section using a piezoresistive element is described, however, the pressure sensor is not limited thereto, and for example, a configuration using a flap-type vibrator, another MEMS vibrator such as a comb electrode, or a vibration element such as a crystal vibrator can also be used.

The entire disclosure of Japanese Patent Application No. 2016-063263 filed Mar. 28, 2016 is expressly incorporated by reference herein.

What is claimed is:

1. A pressure sensor, comprising:
a flexible diaphragm which is flexed by pressure changes; and
a coating layer on one surface of the diaphragm, the coating layer being a single layer containing silicon, nitrogen, and oxygen.

2. The pressure sensor according to claim 1, wherein the coating layer contains silicon oxynitride.

3. The pressure sensor according to claim 1, wherein the coating layer has a nitrogen concentration distribution which varies across a thickness of the coating layer.

4. The pressure sensor according to claim 3, wherein the nitrogen concentration distribution gradually increases from a first side of the coating layer to a second side of the coating layer, the first side of the coating layer being adjacent to the diaphragm, the second side of the coating layer being opposite to the first side.

5. The pressure sensor according to claim 1, wherein
T1 is a thickness of the diaphragm,
T2 is a thickness of the coating layer, and
T2≦T1/20.

6. A method for producing a pressure sensor, comprising:
preparing a substrate;
providing a coating layer on one surface of the substrate, the coating layer being a single layer containing silicon, nitrogen, and oxygen; and
forming a flexible diaphragm in the substrate, the diaphragm being configured to flex due to pressure changes.

7. The method according to claim 6, wherein
the substrate contains silicon, and
in the providing of the coating layer, the one surface of the substrate is heated in an atmosphere containing nitrogen and oxygen to form the coating layer.

8. The method according to claim 6, wherein
the substrate contains silicon, and
in the providing of the coating layer, the one surface of the substrate is heated in an atmosphere containing oxygen, and thereafter is heated in a nitrogen atmosphere to form the coating layer.

9. An altimeter, comprising:
the pressure sensor according to claim 1; and
a housing that houses the pressure sensor.

10. An electronic apparatus, comprising:
the pressure sensor according to claim 1; and
a housing that houses the pressure sensor.

11. A moving object, comprising:
the pressure sensor according to claim 1; and
a housing that houses the pressure sensor.

12. A pressure sensor, comprising:
a pressure sensitive flexible diaphragm; and
a single layer coating on one surface of the diaphragm, the coating containing silicon, nitrogen, and oxygen.

13. The pressure sensor according to claim 12, wherein the coating layer contains silicon oxynitride.

14. The pressure sensor according to claim 12, wherein the coating has a nitrogen concentration distribution which varies across a thickness of the coating layer.

15. The pressure sensor according to claim 14, wherein the nitrogen concentration distribution increases from a lowest concentration adjacent a first side of the coating to a highest concentration adjacent a second side of the coating, the first side of the coating being disposed on the diaphragm, the second side of the coating being opposite to the first side.

16. The pressure sensor according to claim 12, wherein the coating has an oxygen concentration distribution which varies across a thickness of the coating layer.

17. The pressure sensor according to claim 16, wherein the oxygen concentration distribution decreases from a highest concentration adjacent a first side of the coating to a lowest concentration adjacent a second side of the coating, the first side of the coating being disposed on the diaphragm, the second side of the coating being opposite to the first side.

18. The pressure sensor according to claim 14, wherein the coating has an oxygen concentration distribution which varies across a thickness of the coating layer.

19. The pressure sensor according to claim 15, wherein the coating has an oxygen concentration distribution which varies across a thickness of the coating layer, and
the oxygen concentration distribution decreases from a highest concentration adjacent the first side of the coating to a lowest concentration adjacent the second side of the coating.

20. The pressure sensor according to claim 1, wherein
T1 is a thickness of the diaphragm,
T2 is a thickness of the coating layer, and
T2≦T1/20.
